(19) United States
(12) Patent Application Publication
(10) Pub. No.: US 2026/0271184 A1
(43) Pub. Date: Sep. 10, 2026

(54) PRINTED WIRING BOARD

(71) Applicant: KYOCERA Corporation, Kyoto-shi, Kyoto (JP)

(72) Inventor: Chenyu WANG, Chiba-shi, Chiba (JP)

(73) Assignee: KYOCERA Corporation, Kyoto-shi, Kyoto (JP)

(21) Appl. No.: 19/163,443

(22) PCT Filed: Mar. 28, 2024
(86) PCT No.: PCT/JP2024/012576

§ 371 Date: Sep. 9, 2025

(30) Foreign Application Priority Data
Mar. 31, 2023 (JP) 2023-056882
Oct. 30, 2023 (JP) 2023-185517

(51) Int. Cl. H05K 1/02; H05K 1/181

(52) U.S. Cl. CPC H05K 1/0296; H05K 1/181; H05K 2201/093

(57) ABSTRACT

A printed wiring board reduces wiring width while maintaining electrical resistance for a power supply path. The printed wiring board includes a power supply layer including a conductor portion having a first and second ends facing each other on a power supply path, a first and second conductor connection portions protruding from first and second ends, respectively, on the path in a direction away from the conductor portion. The conductor portion consists of a first region interposed between the first end and the second end, and a second region and a third region located opposite each other on both sides of the first region. The second region and the third region each have the same shape obtained by dividing a regular polygon or a circle having an even number of sides of 16 or more in half through the center of the regular polygon or circle.

### TECHNICAL FIELD

The present disclosure relates to a printed wiring board.

### BACKGROUND OF INVENTION

In printed wiring boards, known techniques are used to increase the wiring width between terminals in a power supply path that supplies power in order to ensure sufficient current capacity against voltage drops due to electrical resistance and to accommodate load fluctuations, etc. In addition, in Japanese Unexamined Patent Application Publication No. 2004-39686, a power plane shape that surrounds a power supply end is used to reduce impedance.

### SUMMARY

In an embodiment of the present disclosure, a printed wiring board includes a power supply layer. The power supply layer includes a conductor portion, a first conductor connection portion, and a second conductor connection portion. The conductor portion is located on a power supply path and has a first end and a second end that face each other. The first conductor connection portion is connected to the first end on the path and protrudes from the first end in a direction away from the conductor portion. The second conductor connection portion is connected to the second end on the path and protrudes from the second end in a direction away from the conductor portion. The conductor portion consists of a first region interposed between the first end and the second end, and a second region and a third region located opposite each other and in contact with portions of the first region that are not in contact with the first conductor connection portion and the second conductor connection portion. The second region and the third region each have an identical shape obtained by dividing a regular polygon having an even number of sides of 16 or more or a circle in half through a center of the regular polygon or the circle.

### BRIEF DESCRIPTION OF THE DRAWINGS

FIG. 1A is a schematic diagram illustrating an embodiment of a power supply path.

FIG. 1B is a schematic diagram illustrating another embodiment of a power supply path.

FIG. 2 is an enlarged plan view illustrating a power supply path between a first conductor connection portion and a second conductor connection portion.

FIG. 3A is a table showing the results of a numerical simulation related to the shape of a conductor portion.

FIG. 3B is a table showing the results of a numerical simulation related to the shape of a conductor portion.

FIG. 4A is a diagram illustrating the current direction and current density distribution of a conductor portion obtained by a numerical simulation.

FIG. 4B is a diagram illustrating the current direction and current density distribution of a conductor portion obtained by a numerical simulation.

FIG. 5 is a diagram illustrating another example of a power supply path.

FIG. 6A is a diagram for explaining a power supply path of a Second Embodiment.

FIG. 6B is a table showing the results of a numerical simulation of the power supply path of the Second Embodiment.

FIG. 7A is a diagram illustrating the current direction and current density distribution of a conductor portion of the Second Embodiment obtained by a numerical simulation.

FIG. 7B is a diagram illustrating the current direction and current density distribution of the conductor portion of the Second Embodiment obtained by a numerical simulation.

FIG. 8 is a diagram illustrating the shape of a conductor portion of a comparative example of the Second Embodiment.

FIG. 9A is a diagram illustrating the results of a numerical simulation of the current density distribution related to a conductor portion of a reference shape.

FIG. 9B is a diagram illustrating the results of a numerical simulation of the current density distribution related to the shape of a conductor portion of a comparative example.

FIG. 10A is a diagram for explaining a power supply path between a first conductor connection portion and a second conductor connection portion in a printed wiring board of a Third Embodiment.

FIG. 10B is a table showing the results of a numerical simulation of the resistance value of a conductor portion according to the shape between the first conductor connection portion and the second conductor connection portion in the printed wiring board of the Third Embodiment.

FIG. 11A is a diagram illustrating the current direction and current density distribution of a conductor portion of the Third Embodiment obtained by a numerical simulation.

FIG. 11B is a diagram illustrating the current direction and current density distribution of a conductor portion of the Third Embodiment obtained by a numerical simulation.

FIG. 12 is a diagram illustrating the current direction and current density distribution of a conductor portion of a reference shape according to the Third Embodiment obtained by a numerical simulation.

FIG. 13A is a diagram for explaining a power supply path between a first conductor connection portion and a second conductor connection portion in a printed wiring board of a Fourth Embodiment.

FIG. 13B is a diagram illustrating the results of a numerical simulation for the power supply path between the first conductor connection portion and the second conductor connection portion in the printed wiring board of the Fourth Embodiment.

FIG. 14A is a diagram illustrating a current direction and current density distribution of a conductor portion of the Fourth Embodiment obtained by a numerical simulation.

FIG. 14B is a diagram illustrating a current direction and current density distribution of a conductor portion of the Fourth Embodiment obtained by a numerical simulation.

FIG. 15 is a diagram illustrating a current direction and current density distribution of a conductor portion of a reference shape according to the Fourth Embodiment obtained by a numerical simulation.

### DESCRIPTION OF EMBODIMENTS

Hereafter, embodiments will be described based on the drawings.

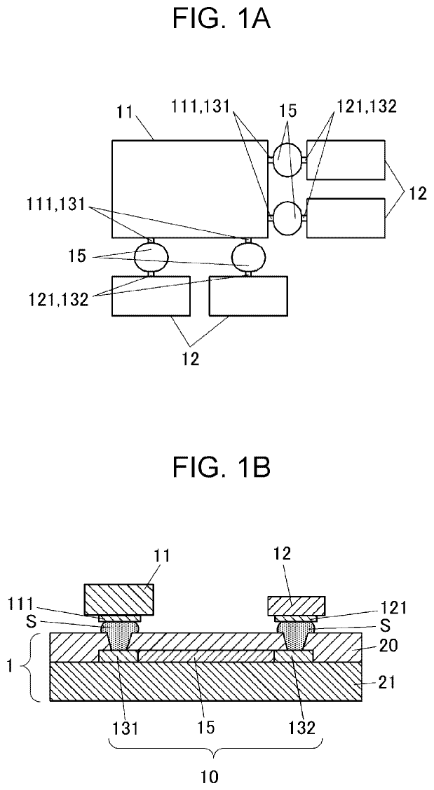

FIG. 1A is a schematic plan view of a power supply path that connects a first IC 11, which is a power supply source, to second ICs 12, which receive the power, in the same layer as the ICs. FIG. 1B is a schematic cross-sectional view of a printed wiring board 1 on which the first IC 11 and the second ICs 12 are mounted, and in which a power supply path is located in the same layer as the ICs.

As illustrated in FIG. 1A, the first IC 11 that serves as a power supply source and the second ICs 12 that receive power are located on the printed wiring board 1. There may be multiple second ICs 12. The multiple second ICs 12 may receive different voltages from each other. The first IC 11 can supply power such as one or more voltages (constant voltages) or currents (constant currents) received by the second ICs 12.

The first IC 11 has output terminals 111. The output terminals 111 are connected to first conductor connection portions 131. Each second IC 12 has an input terminal 121. The input terminal 121 is connected to a second conductor connection portion 132. Each first conductor connection portion 131 and the corresponding second conductor connection portion 132 are connected to each other by a power plane. The power plane is a planar conductor portion 15. A power supply path extends from each output terminal 111 to the corresponding first conductor connection portion 131, conductor portion 15, second conductor connection portion 132, and input terminal 121 in this order.

The first IC 11 and/or the second ICs 12 may be located in a different conductor layer from a power supply layer 10 including the conductor portion 15 in the printed wiring board 1. In this case, each output terminal 111 and corresponding first conductor connection portion 131, and each input terminal 121 and corresponding second conductor connection portion 132 may be connected to each other via a through conductor that penetrates through an insulating layer between the conductor portion 15 and the first IC 11 and/or the second IC 12. When an insulating layer 20 is, for example, a solder resist, the first conductor connection portion 131, which is exposed in an opening in a solder resist, and the output terminal 111 are connected to each other by solder S. The second conductor connection portion 132, which is exposed in an opening in the solder resist, is connected to the input terminal 121 by solder S. The power supply layer 10 may be located in an inner layer of the printed wiring board 1, which has a multi-layer structure.

The sizes of the first IC 11, the second ICs 12, and the conductor portions 15 illustrated in FIGS. 1A and 1B are for illustrative purposes only and may not reflect the actual size ratios.

### First Embodiment

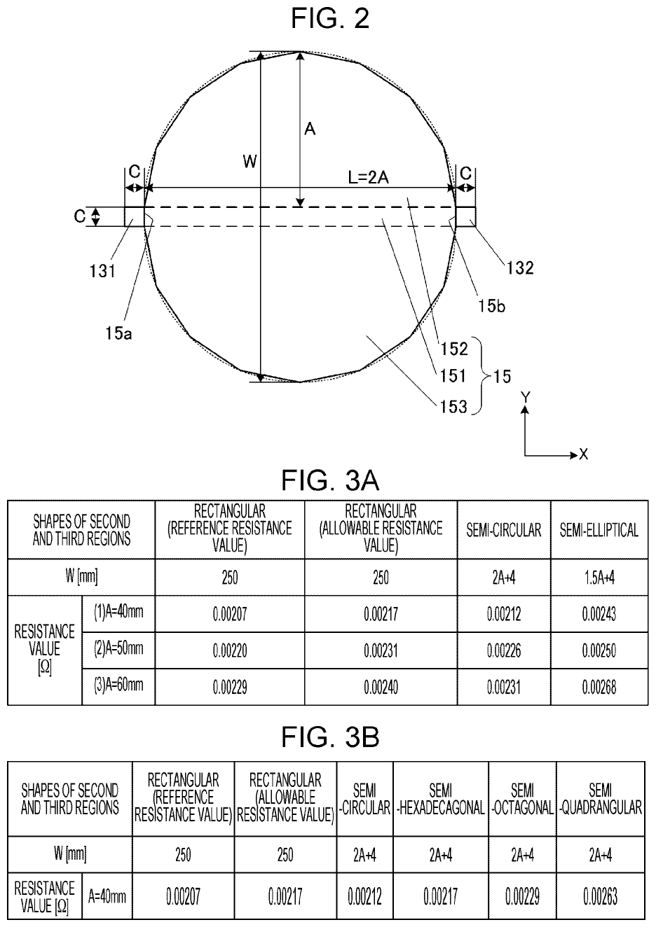

FIG. 2 is an enlarged plan view illustrating the power supply layer 10. The power supply layer 10 constitutes a power supply path between the first conductor connection portion 131 and the second conductor connection portion 132 in a First Embodiment. The direction from the first conductor connection portion 131 to the second connection portion is an X direction, and a direction perpendicular to this X direction is set as a Y direction.

The first conductor connection portion 131 and the second conductor connection portion 132 may each have a square shape with one side having a length C. At least a first end 15a, which is a connection portion between the first conductor connection portion 131 and the conductor portion 15, and a second end 15b, which is a connection portion between the second conductor connection portion 132 and the conductor portion 15, are shaped like parallel straight lines extending in the Y direction in plan view and face each other. The first conductor connection portion 131 protrudes from the first end 15a in a direction away from the conductor portion 15, i.e., the −X direction. The second conductor connection portion 132 protrudes from the second end 15b in a direction away from the conductor portion 15, i.e., the +X direction.

The conductor portion 15 includes a first region 151 having a rectangular shape in plan view and extending in the X direction while being interposed between the first end 15a and the second end 15b, and a second region 152 and a third region 153 that are connected to the first region 151. The second region 152 and the third region 153 are located on either side of the first region 151 in the ±Y direction in a direction perpendicular to the extension direction of the first region 151. That is, the second region 152 and the third region 153 are located opposite each other while in contact with a portion of the first region 151 that is not in contact with either the first conductor connection portion 131 or the second conductor connection portion 132. The second region 152 and the third region 153 each have a shape obtained by dividing a regular hexadecagon into two halves in plan view having the same shape. This shape is hereinafter referred to as a semi-regular hexadecagon. In this embodiment, the dividing line passes through the center of the regular hexadecagon and connects two opposite vertices. The second region 152 and the third region 153 are in contact with the first region 151 at the dividing line of the regular hexadecagon. The length of the first region 151 in the Y direction, which is perpendicular to the extension direction of the first region 151, i.e., along the width direction, is equal to a side length C of the first conductor connection portion 131 and the second conductor connection portion 132. This length in the Y direction is hereinafter referred to as the width. A length L of the first region 151 in the X direction, i.e., the distance between the first end 15a and the second end 15b, is equal to the length of the dividing line of the second region 152 and the third region 153. That is, the semi-regular hexadecagon is inscribed inside a circle of a radius A as indicated by a dotted line. The radius A corresponds to ½ the length L of the first region 151.

Next, a preferred shape of the conductor portion 15 will be described.

As described above, the conductor portion 15 needs to have a small electrical resistance in order to reduce voltage drop and heat generation along the power supply path. The electrical resistance of electrical wiring is proportional to the length and inversely proportional to the cross-sectional area of the wiring, and therefore the cross-sectional area, particularly the width of planar wiring, is set to be greater than the widths of the first conductor connection portion 131 and the second conductor connection portion 132.

However, in regions where the wiring width suddenly increases or decreases, particularly in regions where the width is discontinuous, the current does not immediately diffuse or converge even if the width of the conductor portion 15 is large. Therefore, in a large conventional rectangular conductor portion, there are regions where almost no current flows. Such regions make little contribution to reducing the electrical resistance compared to the increase in area.

The printed wiring board 1 of this embodiment includes the conductor portion 15 having a shape obtained by removing regions that contribute little to reducing the electrical resistance. In other words, the conductor portion 15 has a shape obtained by appropriately removing the corners of a rectangular shape. This reduces the size of the conductor portion 15 while keeping the increase in electrical resistance within a range that does not cause problems.

FIGS. 3A and 3B are tables showing the results of numerical simulations related to the shape of the conductor portion.

In this numerical simulation, the electrical resistance value of the conductor portion 15 is calculated based on the voltage drop when a current of 1 A flows between the first conductor connection portion 131 and the second conductor connection portion 132, each of which is 4 mm×4 mm×0.03556 mm, with an input voltage of 1 V supplied to the first conductor connection portion 131. The insulating layer on which the conductor portion 15, which is a power plane, is formed has a thickness of 30 μm, a relative dielectric constant of 4.6, and a dielectric loss tangent of 0.014, corresponding to R-1766 manufactured by Panasonic (registered trademark). The conductor portion 15 is formed on this insulating layer from copper (electrical conductivity ρ=5.959E+07 S/m) with a thickness of 35.56 μm. The upper surface of the conductor portion 15 is covered with a solder resist having a thickness of 30 μm (relative dielectric constant 4.2, dielectric loss tangent 0.021). The resistance value of the conductor portion 15 under the above conditions was calculated using Cadence Power DC ver. 17 by Cadence Design Systems, Inc. (Cadence; registered trademark).

In FIG. 3A, as an example of a “rectangle”, the conductor portion 15 has a conventional rectangular shape and the resistance value is calculated when the length L of the conductor portion 15 is 2 A and the width W of the conductor portion 15 is 250 mm. This resistance value is shown as a reference resistance value. The length L is the distance between the first conductor connection portion 131 and the second conductor connection portion 132. The width W is the length in the direction perpendicular to the length of the conductor portion 15. In addition, a value of 105% of the reference resistance value, that is, a change rate of 5%, is set as an upper limit, that is, the allowable resistance value. Note that a change rate of 5% or less for the resistance value is used as an evaluation of the connection reliability of a via conductor. This is because a failure is commonly judged to have occurred if the resistance value after environmental reliability testing such as temperature cycling exceeds the initial value by 10%. In a stricter judgment, greater than 5% may be used. We applied this approach to evaluation of connection reliability to the examination of electrical characteristics and decided to use the stricter standard for this evaluation. We adopted a value of 5% or less, which is the value when there is no failure, as the allowable change in the power supply path in this embodiment.

The width of the first region 151, that is, the length perpendicular to the length of the conductor portion 15, is 4 mm, which is the same as that of the output terminal 111 and the input terminal 121.

The rows show the results obtained when a length A is changed to three values, namely, 40 mm, 50 mm, and 60 mm. The length A is half the length L, i.e., the length along which the first region 151 contacts each of the second region 152 and the third region 153 between the first conductor connection portion 131 and the second conductor connection portion 132. The “semicircular” column shows resistance values obtained as the results of a numerical simulation in which the second region 152 and the third region 153 have semicircular shapes obtained by dividing a circle with a radius equal to the length A through the center of the circle. The “semi-elliptical” column shows resistance values obtained as the results of a numerical simulation in which the second region 152 and the third region 153 have semi-elliptical shapes obtained by dividing an ellipse along the major axis of the ellipse. The ellipse has a major axis length equal to the length L and a minor axis length of 2 times ¾ (1.5 times) the length A, i.e., 0.75 times the major axis length.

The results showed that the resistance value when the second region 152 and the third region 153 have semicircular shapes falls within 5% of the reference resistance value regardless of the radius A or length L. The results showed that the resistance value when the second region 152 and the third region 153 have semi-elliptical shapes exceeds the allowable resistance value regardless of the radius A or length L.

FIG. 3B shows the results of a numerical simulation in which the second region 152 and the third region 153 have shapes obtained by dividing a regular polygon inscribed inside the semicircle in half. Here, a case where the radius A is 40 mm is illustrated.

The greater the number of sides that the inscribed regular polygon has, the smaller the reduction ratio of the area relative to the semicircular shape becomes, and the smaller the resistance value becomes. We can see that when the number of sides is 16, the resistance value becomes equal to or less than the allowable resistance value. When the number of sides is greater than 16, the shape becomes closer to a semicircular shape, and therefore the resistance value approaches the resistance value in the case of a semicircle.

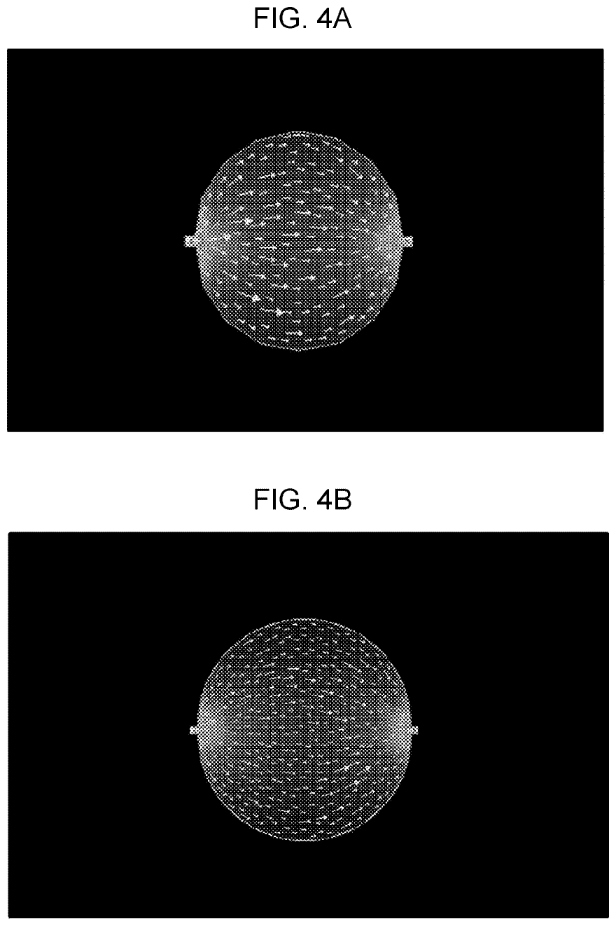

FIG. 4A illustrates the current direction and current density distribution of the conductor portion obtained by numerical simulation for the case where the second region 152 and the third region 153 have semi-regular hexadecagonal shapes. FIG. 4B illustrates the current direction and current density distribution of the conductor portion obtained by numerical simulation for the case where the second region 152 and the third region 153 have semicircular shapes.

In either case, the current is shown to spread from the first conductor connection portion 131 along circular arcs and converges at the second conductor connection portion 132. In addition, the current density is generally high in the vicinity of the first region 151 that extends straight from the output terminal 111 to the input terminal 121, and tends to be relatively low near the peripheries of the second region 152 and the third region 153. Therefore, when the second region 152 and the third region 153 are close to having a circular shape, the conductor portion 15 is less likely to obstruct the current, and therefore an increase in the resistance value is suppressed.

In addition, the first conductor connection portion 131 and the second conductor connection portion 132 are positioned so as to respectively contact the first end 15a and the second end 15b, which are the boundaries of the conductor portion 15, and protrude outward. Therefore, the current flows out from one side of the first conductor connection portion 131 to the conductor portion 15 in a substantially constant direction, and flows into one side of the second conductor connection portion 132 in a substantially constant direction. That is, current does not flow out through the three sides of the first conductor connection portion 131 other than the boundary with the conductor portion 15, and current does not flow in through the three sides of the second conductor connection portion 132 other than the boundary with the conductor portion 15. That is, the current density in the vicinity of the first region 151 can be increased, while the conductor area can be substantially reduced by locally controlling the current density to be small.

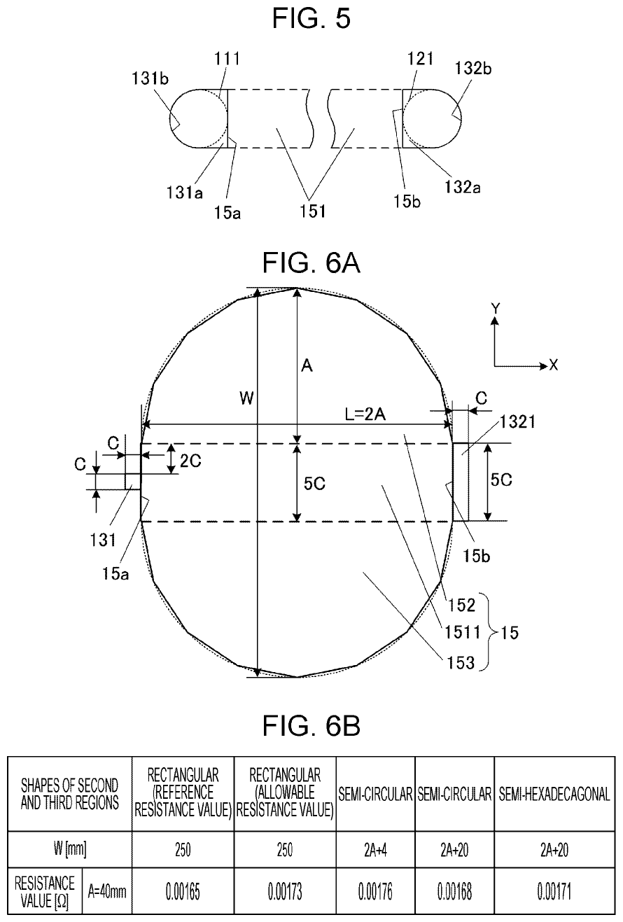

FIG. 5 is a diagram illustrating another example of a power supply path.

In the example in FIG. 5, a first conductor connection portion 131a and a second conductor connection portion 132a are illustrated in an enlarged manner. Their shapes are changed from the square shapes of the first conductor connection portion 131 and the second conductor connection portion 132 in plan view. Similarly to the first conductor connection portion 131 and the second conductor connection portion 132, which have rectangular shapes, the first conductor connection portion 131a and the second conductor connection portion 132a include connection portions with the first end 15a and the second end 15b of the first region 151 that are shaped like straight lines of length C in plan view. The range of a length C/2 from the above-mentioned connection portions of the first conductor connection portion 131a and the second conductor connection portion 132a has a rectangular shape in plan view with a width of length C. In the first conductor connection portion 131a, with respect to the part having a rectangular shape in plan view, a first curved part 131b, which is a part having a semicircular outline in plan view with a diameter of the length C, is connected to the side of the rectangular part on the opposite side from the first region 151. In the second conductor connection portion 132a, with respect to the above-mentioned part having a rectangular shape in plan view, a second curved part 132b, which is a part having a semicircular outline in plan view with a diameter of the length C, is connected to the side of the rectangular part on the opposite side from the first region 151.

Thus, the first conductor connection portion 131a and the second conductor connection portion 132a do not need to have a rectangular shape, in particular a square shape, as long as the connection parts with the first region 151 are shaped like straight lines in plan view. The first conductor connection portion 131a and the second conductor connection portion 132a may have a shape corresponding to the shape of the output terminal 111 or the input terminal 121 etc.

As described above, the printed wiring board 1 of this embodiment includes the power supply layer 10 including the conductor portion 15, the first conductor connection portion 131, and the second conductor connection portion 132. The conductor portion 15 is located on a power supply path and has the first end 15a and the second end 15b that face each other. The first conductor connection portion 131 is connected to the first end 15a on the path and protrudes from the first end 15a in a direction away from the conductor portion 15. The second conductor connection portion 132 is connected to the second end 15b on the path and protrudes from the second end 15b in a direction away from the conductor portion 15. The conductor portion 15 is composed of the first region 151 interposed between the first end 15a and the second end 15b, and the second region 152 and the third region 153 located opposite each other and in contact with portions of the first region 151 that are not in contact with the first conductor connection portion 131 and the second conductor connection portion 132. The second region 152 and the third region 153 each have the same shape obtained by dividing a regular polygon or a circle having an even number of sides of 16 or more in half along a line passing through the center of the regular polygon or circle.

By forming the conductor portion 15 in such a shape, in the printed wiring board 1, the area of the conductor portion 15 can be efficiently reduced from that of the conventional rectangular shape while keeping the electrical resistance of the conductor portion 15 at substantially the same level as that of the conventional rectangular shape. The space resulting from the reduction in the size of the conductor portion 15 can be used for other wiring, etc.

Furthermore, the first end 15a and the second end 15b are shaped like straight lines parallel to each other and have the same length. Therefore, in the printed wiring board 1, a current can be made to efficiently flow from the first conductor connection portion 131 to the second conductor connection portion 132 in a straight line with a uniform current distribution. Therefore, an increase in resistance value can be effectively reduced in the printed wiring board 1. The length of the first end 15a can be defined as the length of the part where the first conductor connection portion 131 is in contact with the conductor portion 15. The length of the second end 15b can be defined as the length of the part where the second conductor connection portion 132 is in contact with the conductor portion 15.

The second region 152 and the third region 153 each have a shape obtained by dividing a regular polygon, and the regular polygon has a size such that the regular polygon is inscribed in a circle whose diameter is equal to the distance between the first end 15a and the second end 15b. With such a shape, the printed wiring board 1 allows the current density distribution to be appropriately controlled and the electrical resistance of a conventional power plane shape to be maintained.

The first conductor connection portion 131 includes the first curved part 131b located in a direction away from the conductor portion 15 relative to the first end 15a. The second conductor connection portion 132 includes the second curved part 132b located in a direction away from the conductor portion 15 relative to the second end 15b. With such a shape, the printed wiring board 1 can be suitably connected according to the shape of the output terminal 111 and the input terminal 121, and a situation in which the area is increased unnecessarily can be avoided.

The first conductor connection portion 131 and the second conductor connection portion 132 may face each other in the X direction, which is perpendicular to the Y direction along the first end 15a. This allows the first conductor connection portion 131 and the second conductor connection portion 132 to be connected to each other by the conductor portion 15 at the shortest distance. Furthermore, the current distribution is approximately symmetrical between the second region 152 and the third region 153, and variations in current density can be reduced in the conductor portion 15.

In addition, in the printed wiring board 1, the length of the first conductor connection portion 131 in the Y direction along the first end 15a and the length of the second conductor connection portion 132 in the Y direction along the second end 15b may be equal to each other. The length of the first conductor connection portion 131 in the direction along the first end 15a may be equal to the length along which the first conductor connection portion 131 is connected to the first end 15a. The length of the second conductor connection portion 132 in the direction along the second end 15b may be equal to the length along which the second conductor connection portion 132 is connected to the second end 15b. In the above-described first conductor connection portion 131 and second conductor connection portion 132, the inflow and outflow of current are easily balanced. Therefore, in the printed wiring board 1, an increase in resistance value can be reduced and an increase in the area of the conductor portion 15 can also be reduced.

### Second Embodiment

A power supply path of a Second Embodiment will be described.

FIG. 6A is a diagram for explaining the power supply path of the Second Embodiment.

This FIG. 6A is an enlarged plan view illustrating a power supply layer 10. The power supply layer 10 constitutes a power supply path between a first conductor connection portion 131 and a second conductor connection portion 1321.

The sizes of the first conductor connection portion 131 and the second conductor connection portion 1321 may be different from each other. For example, the second conductor connection portion 1321 may be shaped like a square with a side length longer than a side length of the first conductor connection portion 131. As an example, the side length of the second conductor connection portion 1321 may be 5 times a side length C of the first conductor connection portion 131 (=4 mm), that is, 20 mm. The lengths of the first end 15a and the second end 15b are equal to the side length of the second conductor connection portion 1321. The side of the second conductor connection portion 1321 on the −X side may be connected to the entire second end 15b. The side of the first conductor connection portion 131 on the +X side is connected to part of the first end 15a. The first conductor connection portion 131 and the second conductor connection portion 1321 face each other in the X direction, which is perpendicular to the Y direction along the first end 15a. For example, one side of the first conductor connection portion 131 may be connected to the first end 15a at the center of the first end 15a in the Y direction, that is, between points at a length of 2 C=8 mm from the two ends of the first end 15a.

FIG. 6B is a table showing the results of a numerical simulation related to the shape of the conductor portion illustrated in FIG. 6A and conductor portions to be compared therewith. As described above, the width of a first region 1511 in the Y direction is 20 mm, and the second conductor connection portion 1321 has a square shape with a side length of 20 mm. The first conductor connection portion 131 with a width of 4 mm is connected to the center of the first end 15a in the Y direction. Parameters not specified have the same values as in the First Embodiment.

The two columns on the left show the reference resistance value and the allowable resistance value, which is 105% of the reference resistance value, when the second region 152 and the third region 153 each have a reference shape that is a rectangular shape with a side length A extending from the first region 1511 in the ±Y direction.

When the second region 152 and the third region 153 connected to the first region 1511, which has a vertical width of 20 mm, each have a semicircular shape with a radius A indicated by a dotted line, the width W of the conductor portion 15 in the Y direction is 2 A+20. The resistance value at this time is smaller than the allowable resistance value. Even when the second region 152 and the third region 153 each have a semi-regular hexadecagonal shape as indicated by solid lines, the resistance value is smaller than the allowable resistance value.

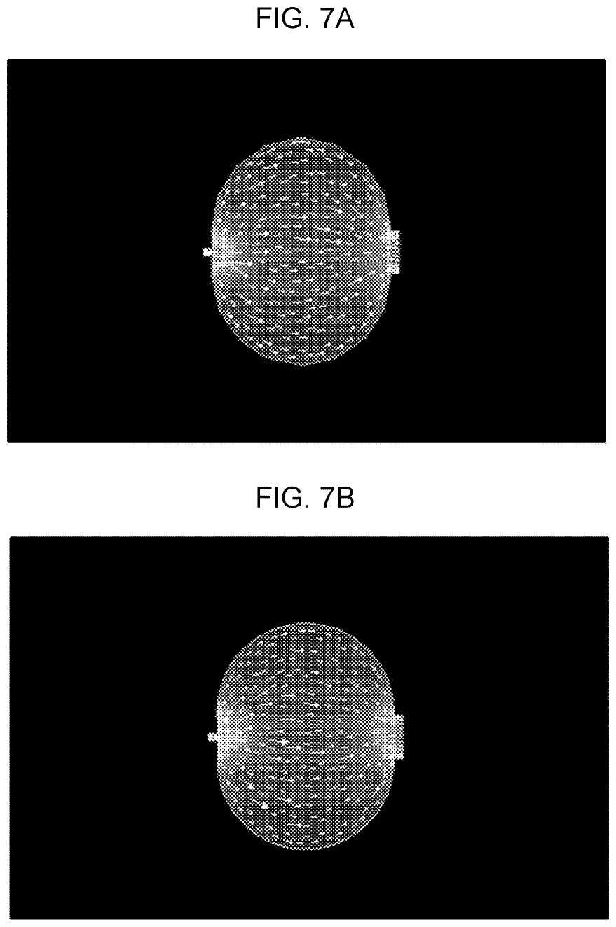

FIGS. 7A and 7B are diagrams illustrating the current direction and current density distribution of the conductor portion in the Second Embodiment obtained by a numerical simulation. FIG. 7A illustrates the case where the second region 152 and the third region 153 have semi-regular hexadecagonal shapes, and FIG. 7B illustrates the case where the second region 152 and the third region 153 have semicircular shapes. In the conductor portions of these shapes, the overall current density variations are smaller than in other parts. On the other hand, as described above, the increase in the resistance is small, and therefore the current flows efficiently in the second region 152 and the third region 153. Since the area of a semi-regular polygon inscribed in a semicircle is smaller than that of a semicircle, the areas of the second region 152 and the third region 153 can be reduced from that of a semicircle in the case of a semi-regular polygon having a number of sides greater than or equal to that of a semi-regular hexadecagon.

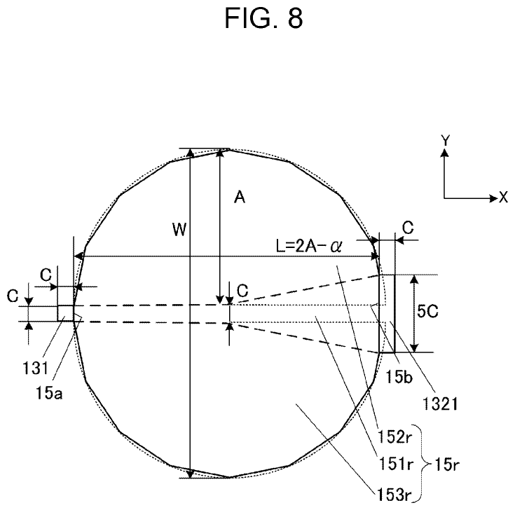

FIG. 8 is a diagram illustrating the shape of a conductor portion 15r in a comparative example.

The width W of a first region 151r is 4 mm in the left half of the conductor portion 15r, and expands radially to 20 mm in the right half of the conductor portion 15r. A second region 152r and a third region 153r, each having a fan-like shape with a radius A, are connected to the first region 151r. The second conductor connection portion 1321 is connected to the conductor portion 15r at a position where the vertical width of the conductor portion 15r is 20 mm. That is, the width W of the conductor portion 15r is 2 A+4 mm, and the length L is shorter than the diameter 2 A. In the example in FIG. 8, as illustrated in FIG. 6B, the resistance value is larger than the allowable resistance value.

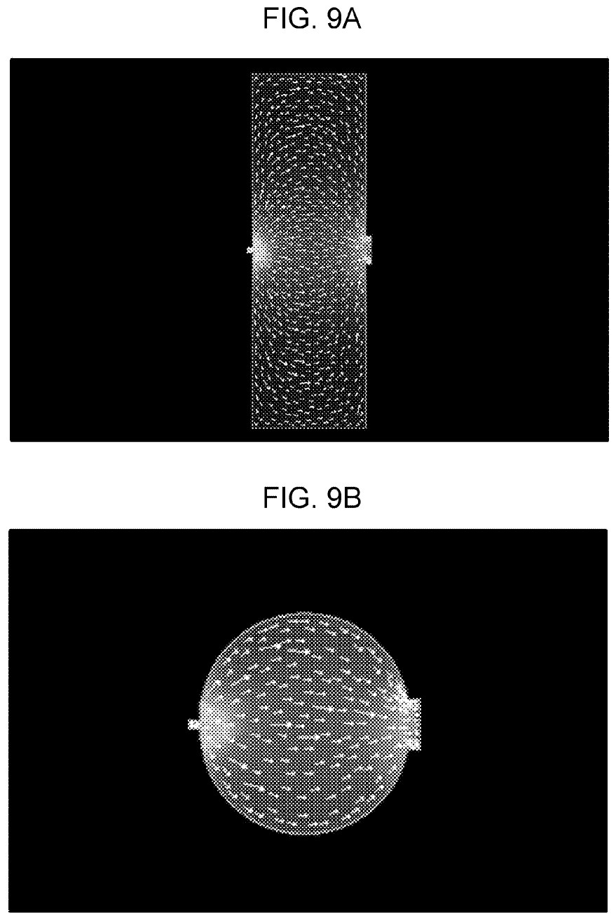

FIG. 9A is a diagram illustrating the results of a numerical simulation of the current density distribution of the conductor portion 15 of a reference shape.

The conductor portion 15 corresponding to the reference resistance value illustrated in FIG. 9A has a rectangular shape as described above. In this case, most of the current flows from the first conductor connection portion 131 to the second conductor connection portion 1321 in a straight line or in arc-like shapes. As a result, the current density near the corners of the second region 152 and the third region 153 is smaller than that along lines connecting the first conductor connection portion 131 and the second conductor connection portion 1321 in an arc-like shape. Such regions have a large effect on increasing the area, but contributes little to reducing the resistance value.

FIG. 9B is a diagram illustrating the results of a numerical simulation of a current density distribution related to the shape of the conductor portion 15.

The current density distribution illustrated in FIG. 9B corresponds to the shape of the conductor portion 15r of the comparative example. The current density distribution in this case is similar to that in FIG. 9A. However, in this case, the current is concentrated near the corners where the second region 152r and the third region 153r meet the second conductor connection portion 1321. Such current concentration parts lead to an increase in the resistance value.

According to the printed wiring board 1 of the Second Embodiment, in the conductor portion 15, the length of the first conductor connection portion 131 in the direction along the first end 15a and the length of the second conductor connection portion 1321 in the direction along the second end 15b may be different from each other. Even if the conductor connection portions connected by the conductor portion 15 have different sizes from each other as needed, the shape of the present disclosure allows the size to be efficiently reduced while reducing an increase in resistance value.

In addition, the first conductor connection portion 131 and the second conductor connection portion 1321 may face each other even if they have different sizes. That is, in the Y direction along the first end 15a and the second end 15b, the first conductor connection portion 131 may be located within a range in the Y direction in which the longer second conductor connection portion 1321 is located. This makes the current density distribution approximately symmetrical between the second region 152 and the third region 153, and the conductor portion 15 can have a reduced bias in current density and allow a current to flow therethrough with low resistance.

### Third Embodiment

Next, a power supply path of a Third Embodiment will be described.

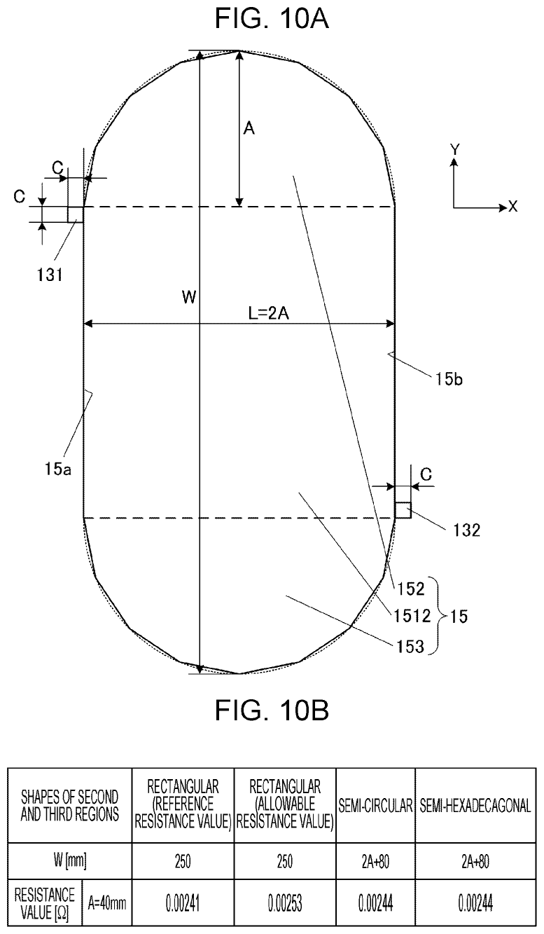

FIG. 10A is a diagram for explaining a power supply path between a first conductor connection portion 131 and a second conductor connection portion 132 in a printed wiring board 1 of the Third Embodiment.

In this power supply path, the first conductor connection portion 131 and the second conductor connection portion 132 are at different positions in the Y direction along the first end 15a and the second end 15b. That is, the first conductor connection portion 131 and the second conductor connection portion 132 do not need to face each other with respect to the Y direction.

In the example in FIG. 10A, the first conductor connection portion 131 may be located at the +Y-side end of the first end 15a in contact with the second region 152, and the second conductor connection portion 132 may be located at the-Y-side end of the second end 15b in contact with the third region 153. That is, the width of the first end 15a and the second end 15b corresponds to an offset width between the first conductor connection portion 131 and the second conductor connection portion 132 in the Y direction.

FIG. 10B is a table showing the results of a numerical simulation of the resistance value of the conductor portion 15 according to the shapes of the first conductor connection portion 131 and the second conductor connection portion 132.

The two columns on the left show the reference resistance value and the allowable resistance value when the conductor portion 15 is a rectangular region with a width W of 250 mm in the Y direction. The two columns on the right show the resistance values for when the width W of the first region 151 is 80 mm, and the second region 152 and the third region 153 have semicircular shapes with a radius A, and when the second region 152 and the third region 153 are shaped like semi-regular hexadecagons inscribed in a semicircle with a radius A. These resistance values are almost the same and are smaller than the allowable resistance value.

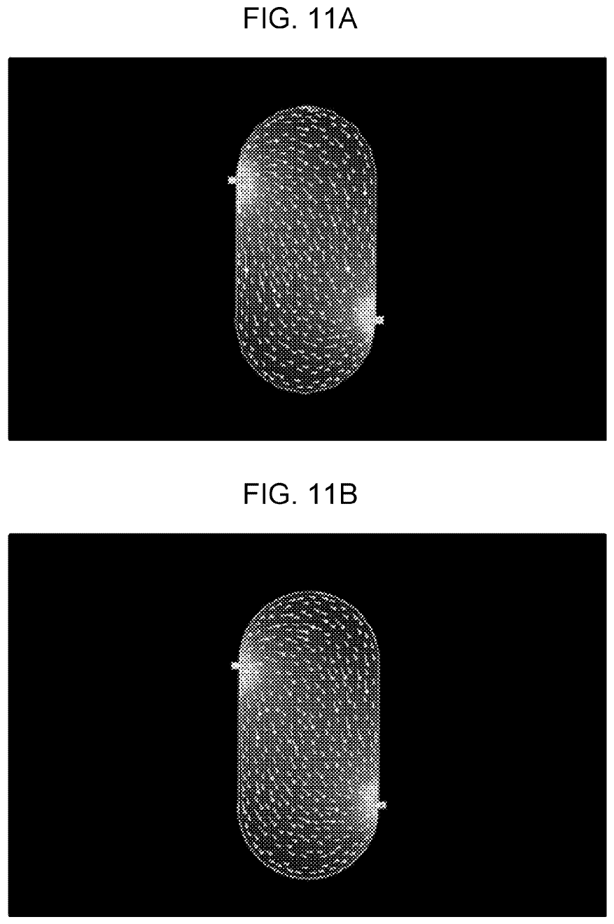

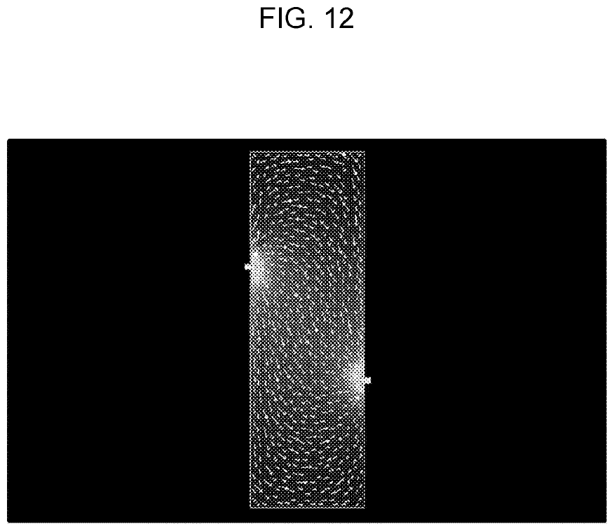

FIGS. 11A, 11B, and 12 are diagrams illustrating the current direction and current density distribution in the Third Embodiment obtained by a numerical simulation. FIG. 11A illustrates the current density distribution when the second region 152 and the third region 153 have semi-regular hexadecagonal shapes. FIG. 11B illustrates the current density distribution when the second region 152 and the third region 153 have semicircular shapes. In either case, the bias of the current density distribution inside the conductor portion 15 is small, that is, an increase in resistance value is reduced, and an unnecessary increase in area is also reduced. That is, the semi-regular hexadecagonal second region 152 and third region 153 have a smaller area than the semicircular second region 152 and third region 153, while obtaining a similar resistance value.

In the current direction and current density distribution of the conductor portion of the reference shape according to the Third Embodiment illustrated in FIG. 12, similarly to the results illustrated in FIG. 9A, there are parts along the edges of the conductor portion 15 where the current density is relatively small. That is, the conductor portion 15 has a disadvantage of having an increased area, in contrast to the effect of reducing the resistance value.

Thus, the first conductor connection portion 131 and the second conductor connection portion 132 of the printed wiring board 1 do not need to face each other in the X direction, which is perpendicular to the Y direction along the first end 15a. Depending on the positional relationship of electronic components to be connected etc., the first conductor connection portion 131 and the second conductor connection portion 132 may not be able to face each other. In such a case, a first region 1512 would include the first end 15a and the second end 15b in a range including the first conductor connection portion 131 and the second conductor connection portion 132 in the Y direction. By connecting the second region 152 and the third region 153, which have semi-regular polygonal shapes having a number of sides greater than or equal to that of a semi-regular hexadecagon, to this first region 1512, both an increase in area and an increase in electrical resistance value can be reduced.

### Fourth Embodiment

Next, a power supply path of a Fourth Embodiment will be described.

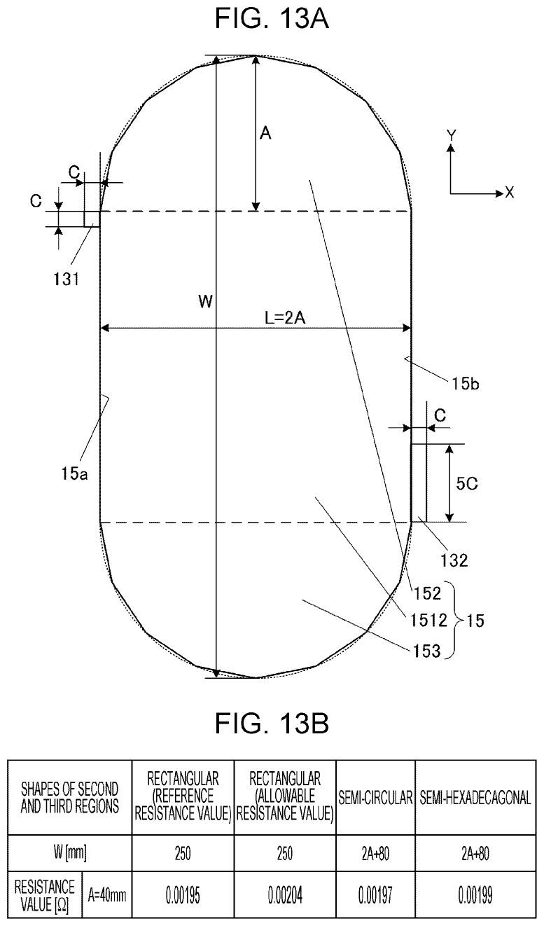

FIG. 13A is a diagram for explaining a power supply path between a first conductor connection portion 131 and a second conductor connection portion 1321 in a printed wiring board 1 of the Fourth Embodiment.

As illustrated in FIG. 13A, in this power supply path, the first conductor connection portion 131 and the second conductor connection portion 1321 have different sizes, and the first conductor connection portion 131 and the second conductor connection portion 1321 do not face each other with respect to the Y direction. That is, in the power supply path of the Fourth Embodiment, the pair of the first conductor connection portion and the second conductor connection portion 1321 of the Second Embodiment is in the positional relationship of the first conductor connection portion and the second conductor connection portion 132 of the Third Embodiment. The other shapes and positional relationships are the same as those of the other embodiments. The case where the second region 152 and the third region 153 have semicircular shapes is illustrated by dotted lines. The case where the second region 152 and the third region 153 have semi-regular hexadecagonal shapes inscribed in the semicircular shape is illustrated by solid lines.

FIG. 13B is a table showing illustrating the results of a numerical simulation of the power supply path between the first conductor connection portion 131 and the second conductor connection portion 1321 in the printed wiring board 1 of the Fourth Embodiment. As illustrated in FIG. 13B, compared to the allowable resistance value, the resistance value of the conductor portion 15 is smaller than the allowable resistance value when the second region 152 and the third region 153 have semicircular shapes or semi-regular hexadecagonal shapes. In other words, if the second region 152 and the third region 153 have semi-regular hexadecagonal shapes, the area can be reduced compared to the semicircular shape while the resistance value can be made equal to or less than the allowable resistance value.

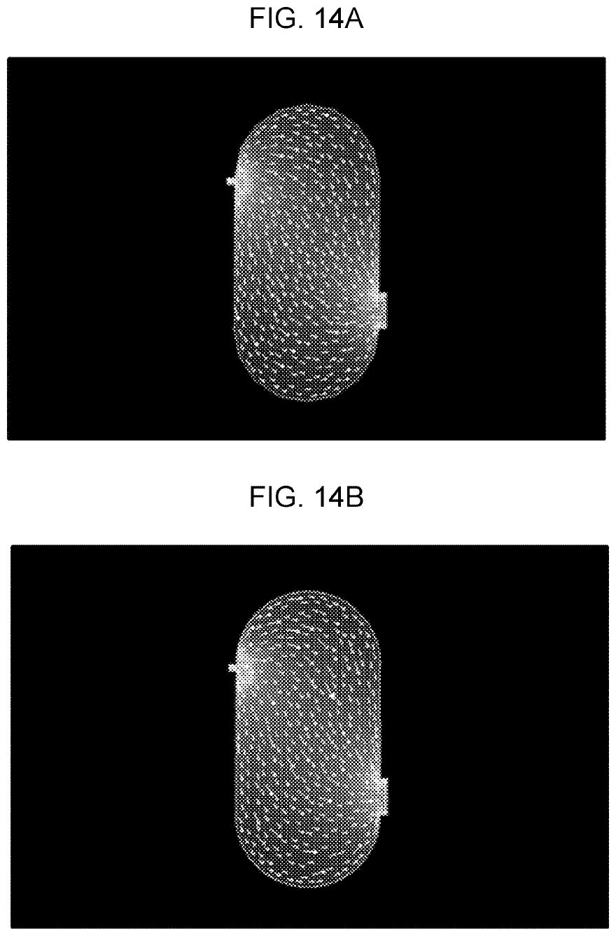

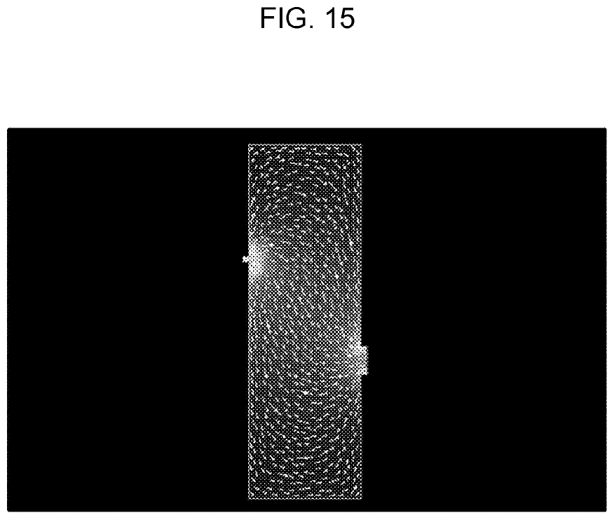

FIGS. 14A, 14B, and 15 are diagrams illustrating the current direction and current density distribution in the Fourth Embodiment obtained by a numerical simulation.

There is no significant bias in the current density distribution regardless of whether the second region 152 and the third region 153 illustrated in FIG. 14A have semi-regular hexadecagonal shapes or the second region 152 and the third region 153 illustrated in FIG. 14B have semicircular shapes. Therefore, we can see that the semi-regular hexadecagonal shaped second region 152 and third region 153 can reduce an increase in resistance value and reduce an increase in area compared to the semicircular shape.

In the current direction and current density distribution of the conductor portion of the reference shape according to the Fourth Embodiment illustrated in FIG. 15, we can see that the current density is smaller near the edges of the conductor portion 15 than in other parts. In other words, we can see that the shape of the conductor portion 15 has a large size compared to the reduction in resistance value.

Thus, in the printed wiring board 1, the length of the first conductor connection portion 131 in the Y direction and the length of the second conductor connection portion 1321 in the Y direction may be different from each other, and the first conductor connection portion 131 and the second conductor connection portion 1321 do not need to face each other in the X-direction. The printed wiring board 1 allows the size of the conductor portion 15 to be flexibly reduced and an increase in the resistance value of the current path to be reduced under conditions related to the position and size of the electronic components.

The above embodiments are merely examples, and various changes are possible.

The power supply layer 10 may be located in an inner layer of the printed wiring board 1, which has a multi-layer structure. In addition, the first IC 11 connected to the power supply layer 10 may be built into or mounted on the wiring board 1. The first IC 11 may be connected to the first conductor connection portion 131 and the second conductor connection portion 132 by wiring using through conductors in an insulating layer. In addition, power may be supplied from the outside without using a power supply IC. By positioning the power supply layer 10 in an inner layer of the printed wiring board 1, the power supply layer 10 is, for example, easily arranged in a circular shape, without any obstructions caused by components mounted on a surface layer of the printed wiring board 1.

For example, the lengths of the first end 15a and the second end 15b may be slightly different from each other. In this case, the first region 151 may be determined based on the longer of the first end 15a and the second end 15b.

The shapes of the first conductor connection portion 131 and the second conductor connection portion 132 do not need to be the same. The shapes of the first conductor connection portion 131 and the second conductor connection portion 132 may differ from each other depending on or regardless of the shapes of the output terminal 111 and the input terminal 121 etc.

In the above embodiment, the shapes of the first conductor connection portion 131 and the second conductor connection portion 132 are described as being a combination of a rectangular shape and a semicircular shape in plan view, but are not limited to these shapes. As long as the parts in contact with the first end 15a and the second end 15b are shaped like straight lines, the first conductor connection portion 131 and the second conductor connection portion 132 may have any suitable shape. The semicircular parts may have a polygonal shape instead. The polygonal shape in this case does not need to be a regular polygonal shape.

In the above embodiments, the power supply layer 10 is an inner layer of the multi-layered substrate, but is not limited to this. The power supply layer 10 may be an outer layer.

Other specific details such as the specific configurations, structures, and sizes illustrated in the above embodiments may be modified as appropriate without departing from the spirit of the present disclosure.

### INDUSTRIAL APPLICABILITY

The present disclosure can be applied to printed wiring boards.

### REFERENCE SIGNS

1 printed wiring board
10 power supply layer
11 first IC
111 output terminal
12 second IC
121 input terminal
131, 131a first conductor connection portion
131b first curved part
132, 132a, 1321 second conductor connection portion
132b second curved part
15, 15r conductor portion
15a first end
15b second end
151, 1511, 1512, 151r first region
152, 1521, 152r second region
153, 1531, 153r third region

1. A printed wiring board comprising:
a power supply layer including a conductor portion located on a power supply path and having a first end and a second end that face each other,
a first conductor connection portion connected to the first end on the path and protruding from the first end in a direction away from the conductor portion, and
a second conductor connection portion connected to the second end on the path and protruding from the second end in a direction away from the conductor portion,
wherein the conductor portion consists of a first region interposed between the first end and the second end, and a second region and a third region located opposite each other and in contact with portions of the first region that are not in contact with the first conductor connection portion and the second conductor connection portion, and
the second region and the third region each have an identical shape obtained by dividing a regular polygon having an even number of sides of 16 or more or a circle in half through a center of the regular polygon or the circle.

2. The printed wiring board according to claim 1,
wherein the first end and the second end are shaped like straight lines that are parallel to each other and have identical lengths.

3. The printed wiring board according to claim 1,
wherein the second region and the third region each have a shape obtained by dividing the regular polygon, and
the regular polygon is of such a size that the regular polygon is inscribed in a circle whose diameter is a distance between the first end and the second end.

4. The printed wiring board according to any one of claim 1,
wherein the first conductor connection portion includes a first curved part located in a direction away from the conductor portion relative to the first end, and the second conductor connection portion includes a second curved part located in a direction away from the conductor portion relative to the second end.

5. The printed wiring board according to any one of claim 1,
wherein the power supply layer is located in an inner layer of the printed wiring board, the printed wiring board having a multilayer structure.

6. The printed wiring board according to any one of claim 1,
wherein a length of the first conductor connection portion in a direction along the first end and a length of the second conductor connection portion in a direction along the second end are equal to each other.

7. The printed wiring board according to any one of claim 1,
wherein a length of the first conductor connection portion in a direction along the first end is different from a length of the second conductor connection portion in a direction along the second end.

8. The printed wiring board according to any one of claim 1,
wherein the first conductor connection portion and the second conductor connection portion face each other in a direction perpendicular to a direction along the first end.

9. The printed wiring board according to any one of claim 1,
wherein the first conductor connection portion and the second conductor connection portion do not face each other in a direction perpendicular to a direction along the first end.
